(19) United States
(12) Patent Application Publication
(10) Pub. No.: US 2013/0329383 A1
(43) Pub. Date: Dec. 12, 2013

(54) MOUNTING APPARATUS FOR CIRCUIT BOARD

(71) Applicants: CHIEN-CHUNG HUANG, New Taipei (TW); ZHENG-HENG SUN, New Taipei (TW)

(72) Inventors: CHIEN-CHUNG HUANG, New Taipei (TW); ZHENG-HENG SUN, New Taipei (TW)

(21) Appl. No.: 13/678,550

(22) Filed: Nov. 16, 2012

(30) Foreign Application Priority Data
Jun. 7, 2012 (CN) 201210185968.7

(51) Int. Cl. H05K 1/18

(52) U.S. Cl. CPC H05K 1/18
USPC 361/752

(57) ABSTRACT

A mounting apparatus includes a chassis, two mounting members, and two screws. The chassis includes a sidewall defining two spaced holes. The mounting members are fixed to a front end of a circuit board. A fixing hole parallel to the circuit board is defined in a front end of each mounting member. The screws extend through the holes of the sidewall and engage in the fixing holes of the mounting members, to perpendicularly fix the circuit board to the sidewall.

### BACKGROUND

1. Technical Field

The present disclosure relates to an apparatus for mounting a circuit board.

2. Description of Related Art

In electronic devices, circuit boards may be mounted inside with a plurality of screws provided to extend through the circuit board and engage in a plurality of posts on a bottom wall of the chassis of the devices. However, fastening so many fasteners manually in chassis can be difficult and inconvenient because of limited space for maneuvering.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of a first embodiment of a mounting apparatus together with a first circuit board.

FIG. 2 is an assembled, isometric view of FIG. 1.

FIG. 3 is similar to FIG. 2, but viewed from another perspective.

FIG. 4 is an exploded, isometric view of two mounting members of a second embodiment of a mounting apparatus together with a second circuit board.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

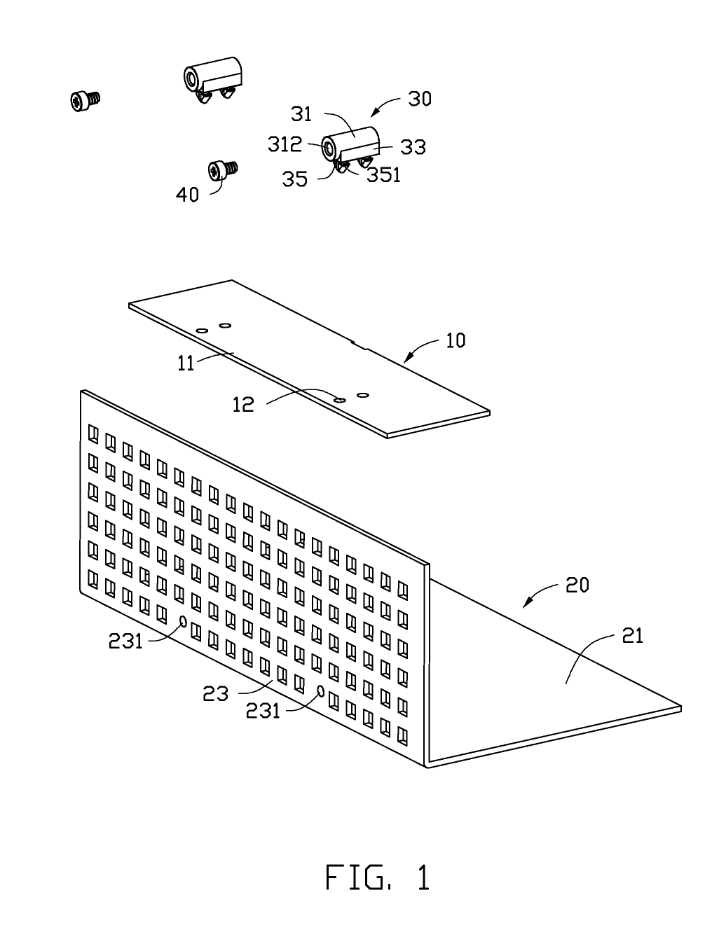

FIG. 1 shows a first embodiment of a mounting apparatus for a first circuit board 10. The mounting apparatus includes a chassis 20, two mounting members 30, and two screws 40.

Two pairs of through holes 12 are defined in a front end 11 of the first circuit board 10, through the top and the bottom of the first circuit board 10.

The chassis 20 includes a bottom wall 21 and a sidewall 23 extending up from the front end of the bottom wall 21. Two spaced holes 231 are defined in the sidewall 23 adjacent to the bottom wall 21.

Each mounting member 30 includes a horizontally extending columnar main body 31. A fixing hole 312 is axially defined in the front end of the main body 31. A base 33 with a flat bottom surface is formed on the bottom of the main body 31. A pair of resilient latching legs 35 extends down from the bottom surface of the base 33. Each latching leg 35 includes two opposite wedge-shaped hooks 351.

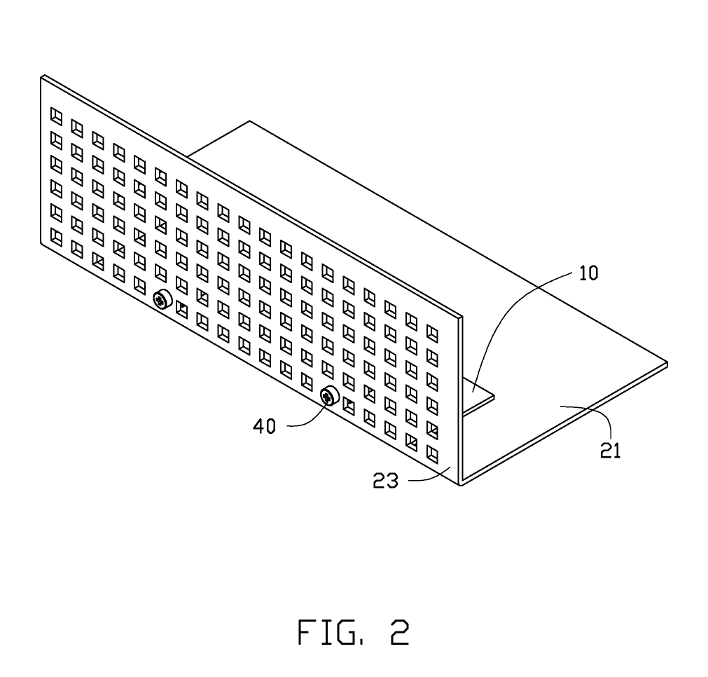

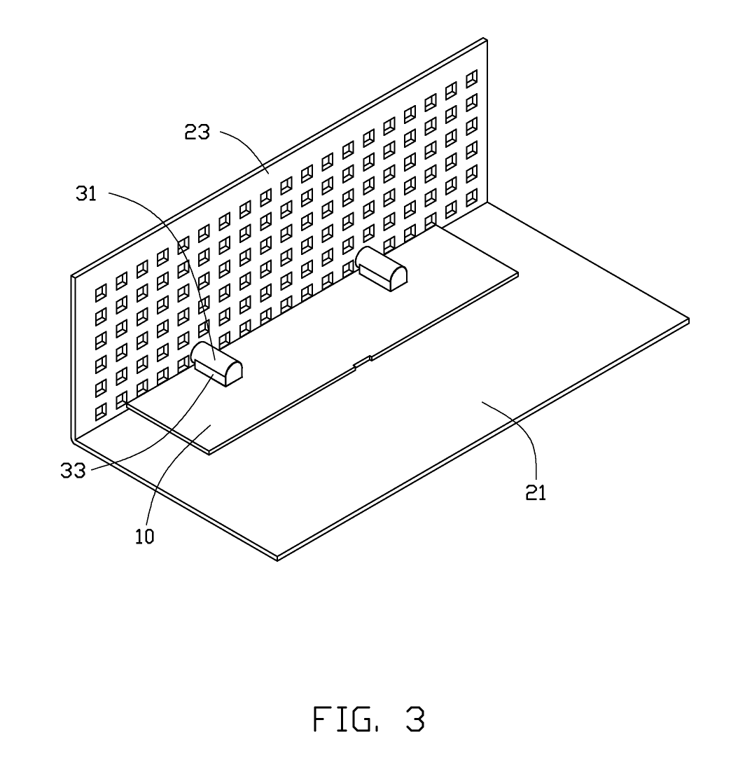

Referring to FIGS. 2 and 3, in assembly, the pairs of latching legs 35 respectively extend through the pairs of through holes 12, to allow the bases 33 to be supported on the first circuit board 10, and to allow the hooks 351 to engage with the bottom of the first circuit board 10. Thereby, the mounting members 30 are fixed to the front end 11 of the first circuit board 10. The fixing holes 312 are parallel to the first circuit board 10. The first circuit board 10 is placed in the chassis 20, to allow the bottoms of the hooks 351 to be supported on the bottom wall 21. The fixing holes 312 are respectively aligned with the holes 231. The screws 40 respectively extend through the holes 231 and engage in the corresponding fixing holes 312. Thereby, the first circuit board 10 is perpendicularly mounted to the sidewall 23.

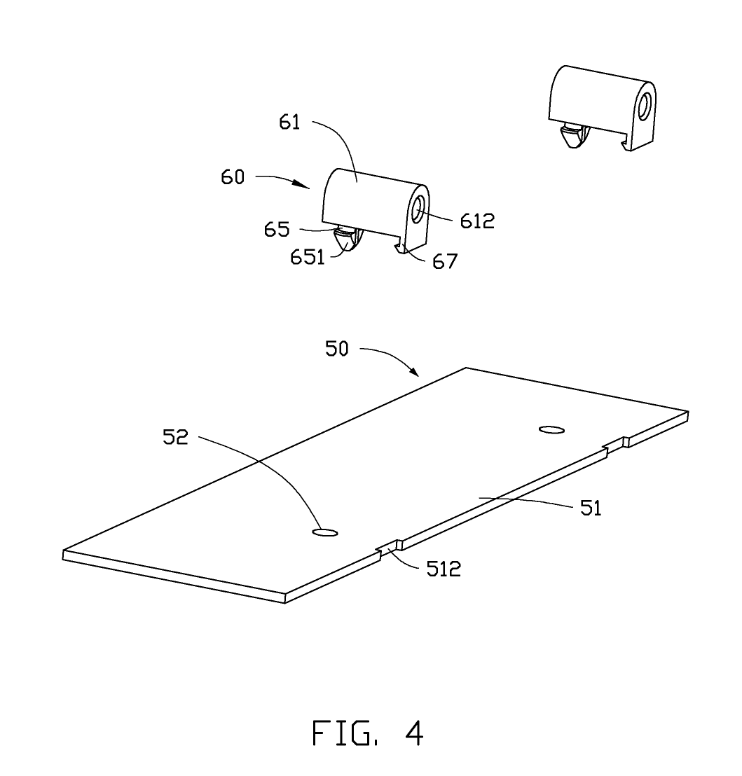

FIG. 4 shows two mounting members 60 of a second embodiment of a mounting apparatus for a second circuit board 50. Two spaced slots 512 are defined in the front end 51 of the second circuit board 50, and two through holes 52 are defined in the front end 51 of the second circuit board 50 respectively adjacent to the slots 512. Each mounting member 60 includes a horizontally extending elongated main body 61. The main body 61 includes a flat bottom surface. A fixing hole 612 is axially defined in a front end of the main body 61. A resilient latching leg 65 including two opposite wedge-shaped hooks 651 extends downward from the bottom surface of the main body 61 away from the first end of the main body 61. An L-shaped latch 67 extends down and back from the bottom of the first end of the main body 61.

In assembly, the latching legs 65 respectively extend through the through holes 52, to allow the hooks 651 to engage with the bottom of the second circuit board 50, and to allow the bottom surfaces of the main bodies 61 to engage with the top of the second circuit board 50. The latches 67 extend through the slots 512 and engage with the bottom of the second circuit board 50. Thereby, the mounting members 60 are fixed to the second circuit board 50. Similar to the first embodiment, two screws 40 are provided to respectively extend through the holes 231 of the sidewall 23 of the chassis 20, and engage in the corresponding fixing holes 612. Thereby, the second circuit board 50 is perpendicularly mounted to the sidewall 23 of the chassis 20.

In each of the first and second embodiments, there are only two screws to be installed when mounting a circuit board, and those are installed from outside of the chassis 20, which is convenient.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A mounting apparatus for a circuit board, comprising:
a chassis comprising a sidewall defining two spaced holes;
two mounting members to be fixed to a front end of the circuit board, wherein a fixing hole parallel to the circuit board is defined in a front end of each mounting member; and
two screws extending through the holes of the sidewall and engaging in the fixing holes of the mounting members, to perpendicularly fix the circuit board to the sidewall.

2. The mounting apparatus of claim 1, wherein each mounting member comprises a pair of resilient latching legs extending down, the pairs of resilient latching legs of the mounting members extend through two pairs of through holes defined in the circuit board and engage with a bottom of the circuit board.

3. The mounting apparatus of claim 2, wherein the chassis further comprises a bottom wall perpendicularly connected to a bottom of the sidewall, the holes of the sidewall are arranged adjacent to the bottom wall, and the resilient latching legs of the mounting members are supported on the bottom wall.

4. The mounting apparatus of claim 2, wherein each resilient latching leg comprises two opposite wedge-shaped hooks.

5. The mounting apparatus of claim 2, wherein each mounting member further comprises a horizontally extending columnar main body, and a base with a flat bottom surface formed on a bottom of the main body, the fixing hole is axially defined in a front end of the main body, and the pair of resilient latching legs extend down from the bottom surface of the base.

6. The mounting apparatus of claim 1, wherein each mounting member comprises an L-shaped latch extending down and back, and a resilient latching leg extending down, the latches of the mounting members extending through two slots defined in the front end of the circuit board and engage with a bottom of the circuit board, and the resilient latching legs of the mounting members extend through two through holes defined in the circuit board and engage with the bottom of the circuit board.

7. The mounting apparatus of claim 6, wherein the chassis further comprises a bottom wall perpendicularly connected to a bottom of the sidewall, the holes of the sidewall are arranged adjacent to the bottom wall, and the resilient latching legs of the mounting members are supported on the bottom wall.

8. The mounting apparatus of claim 6, wherein each resilient latching leg comprises two opposite wedge-shaped hooks.

9. A mounting apparatus for a circuit board, comprising:
a chassis comprising a sidewall; and
a mounting member fixed to the sidewall, and comprising a pair of resilient latching legs,
wherein, in mounting the circuit board, the pair of resilient latching legs respectively extend through two through holes defined in the circuit board and engage with a bottom of the circuit board.

10. The mounting apparatus of claim 9, wherein the chassis further comprises a bottom wall perpendicularly connected to a bottom of the sidewall, the mounting member is arranged adjacent to the bottom wall, the bottom wall is parallel to the circuit board, and the resilient latching legs of the mounting member are supported on the bottom wall.

11. The mounting apparatus of claim 9, wherein the mounting member further comprises a horizontally extending columnar main body, and a base with a flat bottom surface formed on a bottom of the main body, for engaging with a top of the circuit board, the pair of resilient latching legs extend down from the bottom surface of the base.

12. The mounting apparatus of claim 9, wherein each resilient latching leg comprises two opposite wedge-shaped hooks.

13. A mounting apparatus for a circuit board, comprising:
a chassis comprising a sidewall; and
a mounting member fixed to the sidewall, and comprising an L-shaped latch, and a resilient latching leg,
wherein, in mounting the circuit board, the latch extends through a slot defined in the front end of the circuit board and engages with a bottom of the circuit board, and the resilient latching leg extends through a through hole defined in the circuit board and engages with the bottom of the circuit board.

14. The mounting apparatus of claim 13, wherein the chassis further comprises a bottom wall perpendicularly connected to a bottom of the sidewall, the mounting member is arranged adjacent to the bottom wall, the bottom wall is parallel to the circuit board, and the resilient latching leg of the mounting members is supported on the bottom wall.

15. The mounting apparatus of claim 13, wherein the resilient latching leg comprises two opposite wedge-shaped hooks.
